(19) United States
(12) Patent Application Publication
(10) Pub. No.: US 2026/0223745 A1
(43) Pub. Date: Jul. 30, 2026

(54) HIGH POWER DENSITY FLIP CHIP SEMICONDUCTOR PACKAGING

(71) Applicants: Dynex Semiconductor Limited, Lincoln (GB); Zhuzhou CRRC Times Semiconductor Co. Ltd, Zhuzhou, Hunan (CN)

(72) Inventor: Yangang WANG, Lincoln (GB)

(21) Appl. No.: 19/141,654

(22) PCT Filed: Dec. 22, 2022
(86) PCT No.: PCT/EP2022/087549

§ 371 Date: Jun. 20, 2025

(51) Int. Cl. H10W 90/10; H10W 40/20; H10W 74/00; H10W 90/00

(52) U.S. Cl. CPC H10W 90/10; H10W 40/233; H10W 40/242; H10W 74/00; H10W 90/736

(57) ABSTRACT

Semiconductor packaging designs and methods with flip chip wireless bonding technology, in a baseplate and substrate free structure. One or more dies are attached directly to power terminals of a semiconductor packages, and encapsulated by an encapsulating material.

### FIELD OF THE DISCLOSURE

The present application relates to packaging for semiconductor devices, and in particular but not exclusively to flip chip power semiconductor packaging.

### BACKGROUND

Power density, frequency, temperature, efficiency and reliability are critical indexes for power semiconductor packaging, especially for advanced IGBT and WBG packaging for applications of such as Automotive, Renewable Energies and Aerospace, that typically have higher performance and reliability requirements then other industrial and consumer end users. Conventional plastic packaging structures, as well as other recently developed packaging structures such as direct liquid cooling (DLC) and double side cooling (DSC) often struggle to meet the ever growing requirements for semiconductor devices in these industries. As a result, and following the development of advanced power semiconductor chips, such as the latest generation IGBT, SIC MOSFET and GaN HEMT devices, semiconductor packaging has become a limiting factor of power module products, and the advantages provided by the high performance power chips are not fully realised in existing products.

As used herein, ‘flip chip’ refers to a connection technology for interconnecting dies such as semiconductor devices and integrated circuit chips, among others, to external circuitry. Generally speaking, under the flip chip techniques, connections such as bonding pads or solder bumps are provided on a ‘top side’ of a chip during the processing of the chip wafer. After this, and to mount the chip to the desired external circuitry, the chip is turned over, or ‘flipped’, such that its ‘top side’ faces towards the external circuitry. A structure containing a device mounted using this technique may be referred to as a flip chip package or assembly. Examples of state-of-the-art flip chip assemblies are illustrated in FIG. 1b and c. As shown in these figures, the process of flipping the chip results in the bonding pads of the chip facing ‘down’ towards the electrodes of the external circuitry when mounted. In contrast, FIG. 1a illustrates an example of a state-of-the-art wire bonding semiconductor package, in which the chip is mounted to the external circuitry without being ‘flipped’ such that the bonding pads of the chip are provided facing ‘up’ (i.e. on the opposite side of the mounted chip to the external circuitry). As a result, in the example of FIG. 1a, bonding wires are used to provide a connection between the bonding pads of the chip and the electrodes of the external circuitry. It will be understood that references to positional terms such as ‘top side’, ‘up’ and ‘down’ are made for ease of reference to the conceptual illustrations, and are not intended to be of limiting nature.

Advantageously, the resulting flip chip assemblies can be produced with a smaller profile than corresponding assemblies utilising traditional interconnection techniques, as the chip can often be mounted directly to the external circuitry and utilise shorter connection wires between the bonding pads of the chip and the electrodes of the external circuitry. For these and other reasons, flip chip assemblies are utilised in a wide variety of applications.

However, the increased complexity of flip chip designs often means that they are not suitable for unaided manual installation or replacement. Additionally, the expansion and contraction of the assemblies (for example, as they heat and cool during use) can damage the connections between the chip and the rest of the assembly, limiting the maximum device size. These issues are particularly pronounced in high power density devices, with many flip chip assemblies only being suitable for low power operations due, in part, to their poor thermal performance and the subsequent effects for the long term operational reliability of the device.

The Applicants have therefore recognised a need for improvements in semiconductor packaging, and in particular for improvements flip chip power semiconductor packaging.

U.S. Pat. No. 7,301,235 (B2) relates to a plurality of flip chip devices which are arranged in a planar fashion in a common housing. U.S. Pat. No. 9,218,987 (B2) relates to a top-side cooled semiconductor package with a stacked interconnection plate. U.S. Pat. No. 7,492,043 (B2) relates to a power module flip chip package with conductive bumps electrically connected to a gate terminal, a source terminal, and a drain terminal of a power semiconductor device. U.S. Pat. No. 6,921,968 (B2) relates to a stacked flip-chip package comprises a substrate having an opening, a back-to-face chip module, and an encapsulant. U.S. Pat. No. 8,604,597 (B2) relates to a multi-die package comprising a lead frame structure and three dies including a first flip chip die, a second flip chip die and a third flip chip die stacked vertically.

### SUMMARY

Aspects and preferred features are outlined in the accompanying claims.

The present disclosure generally relates to a semiconductor packaging designs with flip chip wireless bonding technology. The packages may be provided with dual side chip cooling structures via the power terminals, and a high temperature and high reliability encapsulation material. Accordingly, increases in the power density are facilitated by flip chip planar bonding of one or more dies to the power terminals, to thereby provide a baseplate and substrate free structure. Parasitics may be reduced via mutual inductance cancelation in the power loop to provide a high frequency and high efficiency packaging.

As such, modules and packaging according to the present disclosure may be utilised in a variety of applications, including but not limited to Integrated Power Module (IPM) packaging, power IC packaging, power device discrete packaging, and embedded 3D packaging.

According to a first aspect of the present disclosure, there is provided a semiconductor module, comprising:
a plurality of semiconductor dies, the plurality of semiconductor dies comprising at least one first semiconductor die and at least one second semiconductor die, each of the first and second semiconductor dies comprising a first surface and an opposite second surface;
a first gate terminal operably connected to the first surface of the first semiconductor die;
a second gate terminal operably connected to the first surface of the second semiconductor die;
a first power terminal attached to the second surface of the first semiconductor die and the first surface of the second semiconductor die;
a second power terminal attached to the first surface of the first semiconductor die;
a third power terminal attached to the second surface of the second semiconductor die; and
an encapsulant encapsulating the plurality of the semiconductor dies and at least part of the first, second and third power terminals.
The semiconductor module may be a power semiconductor module, wherein the plurality of semiconductor dies is a plurality of power semiconductor dies, such as Si MOSFET, IGBT and SIC MOSFET, GaN HEMT chips or modules.

The semiconductor dies of the module may form a half-bridge structure, which is a structure suitable for use in many power semiconductor applications.

A semiconductor module or package according to the present disclosure comprises a plurality of dies attached to the power terminals. For example, the at least one first semiconductor die and the at least one second semiconductor die may be directly attached to the respective first, second and third power terminals. Any suitable attachment means or technology may be used, including soldering and/or sintering, or other joining technologies such as direct copper bonding (DCB) or direct lead bonding (DLB). In implementations, the joining technology is selected to be suitable for high temperature operations.

Attaching the semiconductor dies or chips to the power terminals facilitates the removal of baseplates and/or substrates in the semiconductor package. As a result, a semiconductor module according to the present disclosure may be provided with a compact and low volume structure, compared to equivalent state-of-the-art semiconductor modules. It will be understood that equivalent semiconductor modules may refer to semiconductor modules with similar power densities, frequencies and operating temperature ranges, and intended for similar applications.

Additionally, the structure of the semiconductor module may result in overlap between the power terminals, and in particular between the first power terminal and the second/third power terminals. Therefore, in implementations the first power terminal comprises regions which overlap with the second and/or third power terminals. The overlap and closer proximity of the power terminals (e.g. due to the lack of substrates and/or baseplates) in the semiconductor module may facilitate mutual inductance cancellation of the power loop inductances, to thereby reduce a total module inductance. Additionally, the use of flip chip packaging technology facilitates a reduction in the length of, or in some cases a complete removal of, chip to terminal bonding wires. The reduced length or absence of bonding wires may further reduce the total inductances of the system, by both further reducing power loop inductances and facilitating reduction in a gate/control loop inductances and common source inductances. This in turn may improve the efficiency of the modules, particularly in high frequency switching and/or fast communication applications.

The encapsulant may further enhance a mechanical stability of the module, and provide additional environmental protection (e.g. against high humidity or high temperature environments). The encapsulant may comprise any encapsulating material suitable for the intended operating temperatures of the module, such as a (high temperature) epoxy moulding compound.

Thus, various features of the module, including the removal of failure points such as bonding wires, silicone gel and substrate/baseplate attachment layers, as well as the use of sintering technologies for high reliability and high temperature attachments between layers and the high mechanical stability provided by the encapsulating material, may facilitate significant increases in the reliability of the semiconductor packages. This is particularly advantage for applications with relatively long operational lifetimes, with some semiconductor packages required or intended to remain operational for a decade or more.

Part of the power terminals may extend beyond the encapsulating material. For example, each of the first, second and third power terminals may comprise a first surface and an opposite second surface, wherein:
the first surfaces of the first and second power terminals are attached to the first semiconductor die;
the first surfaces of the first and third power terminals are attached to the second semiconductor die; and
the second surfaces of the first, second and third power terminals extends beyond the encapsulant.

By extending beyond the encapsulant, the power terminals may provide enhanced cooling capabilities for the semiconductor module. For example, the second surface of one or more of the power terminals may be attached to a heatsink or other cooling device, via an electrically insulating thermal interface material. The semiconductor module may therefore be provided with cooling technologies suitable for its intended or desired functionality, for example single sided cooling or double sided cooling technologies, by e.g. attaching one or more heatsinks to the various power terminals.

Advantageously, the provision of the cooling of the semiconductor dies via the power terminals may reduce a thermal resistance of the module. This is due to a smaller number of layers and/or interface layers through which the heat produced by the chips must travel to reach the heatsinks, compared to e.g. a module comprising additional substrates and/or baseplates. Thus, the module according to the present disclosure facilitates enhanced heat dissipation via both the top and bottom surfaces of the modules, to thereby generally provide lower operating temperature and enhanced uniformity in chip temperatures.

The heatsinks may be, for example, direct liquid pin fin plates, or utilise any other heatsink technology.

In implementations, the at least one first semiconductor die comprises at least two first semiconductor dies, and the at least one second semiconductor die comprises at least two second semiconductor dies. The at least two first semiconductor dies and the at least two second semiconductor dies may each comprise a diode or diode, such as a fast reaction diode (FRD) or schotkky diode (SBD), and a transistor, such as an IGBT or a MOSFET.

Advantageously, the semiconductor dies may be provided in a symmetric configuration, i.e. such that the configuration of the first semiconductor dies mirrors that of the second semiconductor dies along an axis. For example, the plurality of semiconductor dies may be provided in a row, and arranged such that the diodes of the first and second semiconductor dies are positioned between the transistors of the first semiconductor and second semiconductor dies. A symmetric dies layout may assist in balancing the parasitics of the dies, for example to provide balanced high and low side parasitics in a half-bridge structure.

Such a configuration of the semiconductor dies further advantageously facilitates power scaling of the module for use in higher power operations, for example by providing additional rows of semiconductor dies. In one implementation, the at least two first semiconductor dies comprise at least four first semiconductor dies, and the at least two second semiconductor dies comprise at least four second semiconductor dies. The at least four first semiconductor dies and the at least four second semiconductor dies may each comprises two or more diodes and two or more transistors, with the diodes and transistors arranged such that the diodes of the first and second semiconductor dies are each positioned between the transistors of the first semiconductor and second semiconductor dies. The semiconductor module may therefore comprise multiple rows of semiconductor dies, each row comprising a similar or identical configuration.

Additionally or alternatively, the power density of the of the semiconductor module may be increased by providing a stacked semiconductor module. For example, additional semiconductor dies may be provided which are separated from the first and second semiconductor dies by one or more power terminals. In one implementations, the plurality of semiconductor dies additionally comprises at least one third semiconductor die and at least one fourth semiconductor die, each of the third and fourth semiconductor dies comprising a first surface and an opposite second surface;
a third gate terminal operably connected to the first surface of the third semiconductor die;
a fourth gate terminal operably connected to the first surface of the fourth semiconductor die;
a fourth power terminal attached to the second surface of the third semiconductor die and the first surface of the fourth semiconductor die;
the second power terminal comprising a first surface attached to the first semiconductor die and an opposite second surface, wherein the second surface is attached to the first surface of the third semiconductor die;
the third power terminal comprising a first surface attached to the second semiconductor die and an opposite second surface, wherein the second surface is attached to the second surface of the fourth semiconductor die; and
wherein the encapsulant encapsulates at least part of the fourth power terminal.

This structure may further be extended to any desired number of stacked semiconductor layers or structures. For example, the plurality of semiconductor dies, second power terminal and third power terminal may form a first module layer between a first surface of the first power terminal and a first surface the fourth power terminal; and the semiconductor module may further comprise:
one or more second module layers, the one or more second module layers comprising an identical structure to the first module layer; and
one or more further power terminals, attached to the second module layers; wherein a first one of the second module layers is attached to a second surface of the fourth power terminal.

In an implementation, the one or more second module layers comprise a plurality of second module layers forming a stacked structure; and
the one or more further power terminals interleave the second module layers in the stacked structure, such that the second module layers are separated from one another by respective further power terminals.

The semiconductor modules of the present disclosure may therefore advantageously provide a scalable solution to the differing power density requirements of various applications, as multiple semiconductor structures and power terminals can be stacked together in an alternating fashion to increase the power capabilities of the overall module.

In all cases, a frame such as a plastic frame may be attached to the power terminals, and the module may be filled with an encapsulation material such as a silicone gel or moulding compound for encapsulation.

In an implementation, the power terminals may comprise isolating substrates (e.g. ceramic substrates) with extended metal sections to provide connection regions for the power terminals. Alternatively, the power terminals may comprise (metal) power leads. In a further implementation, the packaging may be an embedded packaging and the power terminals may comprise multilayer PCBs.

According to a second aspect of the invention, there is provided a method of manufacturing a power semiconductor module, comprising:
attaching a plurality of semiconductor dies to a first power terminal, wherein the plurality of semiconductor dies comprises at least one first semiconductor die and at least one second semiconductor die, each of the first and second semiconductor dies comprising a first surface and an opposite second surface, the first power terminal attached to the second surface of the first semiconductor die and the first surface of the second semiconductor die;
operably connecting a first gate terminal operably to the first surface of the first semiconductor die;
operably connecting a second gate terminal to the first surface of the second semiconductor die;
attaching a second power terminal to the first surface of the first semiconductor die; attaching a third power terminal to the second surface of the second semiconductor die; and
and encapsulating the plurality of the semiconductor dies and at least part of the first, second and third power terminals.

The at least one first semiconductor die and the at least one second semiconductor die may be directly attached to the respective first, second and third power terminals via soldering and/or sintering, or any other suitable joining technologies such as DCB or DLB.

The method may further comprising curing the semiconductor module e.g. via a heat curing process, to strengthen the encapsulating material and further improve the mechanical stability of the resulting module.

The method may further comprise forming a stacked semiconductor module as describe above, for example by:
attaching a second plurality of semiconductor dies to a fourth power terminal, wherein the plurality of semiconductor dies comprises at least one third semiconductor die and at least one fourth semiconductor die, each of the third and fourth semiconductor dies comprising a first surface and an opposite second surface, the fourth power terminal attached to the second surface of the third semiconductor die and the first surface of the fourth semiconductor die;
operably connecting a third gate terminal operably to the first surface of the third semiconductor die;
operably connecting a fourth gate terminal to the first surface of the fourth semiconductor die;
attaching the second power terminal to the first surface of the third semiconductor die, wherein the first and third semiconductor dies are attached to opposite surfaces of the second power terminal;
attaching the third power terminal to the second surface of the fourth semiconductor die, wherein the second and fourth semiconductor dies are attached to opposite surfaces of the third power terminal; and
wherein encapsulating the plurality of the semiconductor dies and at least part of the first, second and third power terminals comprises encapsulating at least part of the fourth power terminal.

The method may further comprise attaching a heatsink or other cooling device to one or more of the first, second, third and/or fourth power terminals.

### BRIEF DESCRIPTION OF THE FIGURES

Some preferred embodiments of the invention will now be described, by way of example only and with reference to the accompanying drawings, in which:

FIGS. 1a-c illustrate semiconductor packages according to the state-of-the-art.

FIG. 2 illustrates a flip chip semiconductor package according to an embodiment of the disclosure.

FIG. 3 illustrates an alternative flip chip semiconductor package according to an embodiment of the disclosure.

FIG. 4 illustrates a double layer flip chip semiconductor package according to an embodiment of the disclosure.

FIG. 5 illustrates a four-layer flip chip semiconductor package according to an embodiment of the disclosure.

FIG. 6 illustrates a double sided cooling (DSC) flip chip semiconductor package according to an embodiment of the disclosure.

FIG. 7a and b illustrate an assembly process for a flip chip semiconductor package according to an embodiment of the disclosure.

FIG. 8a and b illustrate another assembly process for a flip chip semiconductor package according to an embodiment of the disclosure.

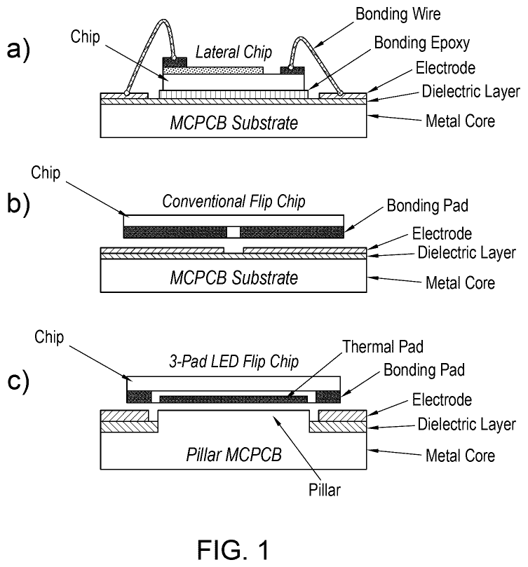

### DETAILED DESCRIPTION OF THE EMBODIMENTS

It will be understood that references throughout this disclosure to positional terms such as ‘top side’, ‘lower’, ‘up’ and ‘down’ are made for ease of reference to the conceptual illustrations, and are not intended to be of limiting nature.

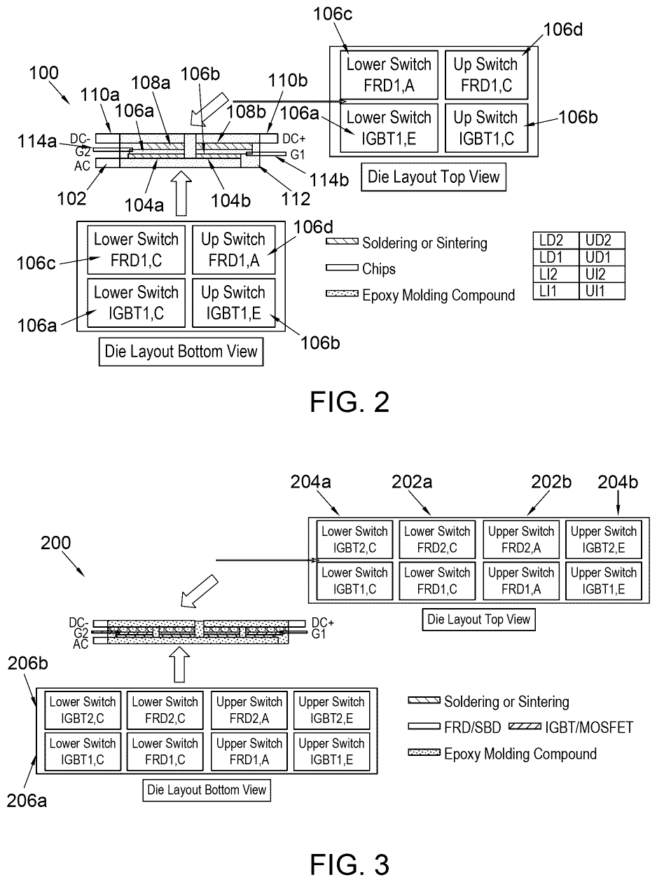

FIG. 2 illustrates a schematic cross-sectional view of a flip chip semiconductor package 100 according to an embodiment of the disclosure. The package comprises four semiconductor dies 106a-d or chips in a single layer half bridge configuration, such as for a DC to DC converter. The chips 106a-d are provided between a first power terminal 102 and second and third power terminals 110a, b.

Package 100 comprises a flip chipped structure, as shown by gate terminals 114a and b being provided on the opposite sides of chips 106a, b, with gate terminal 114a connected to an ‘upper’ side of chip 106a and gate terminal 114b connected to a ‘lower’ side of chip 106b. In other words, this means that chip 106b (as well as chip 106d) are flipped relative to chips 106a and c. This structure is further shown by the top and bottom die layout views accompanying package 100 in FIG. 2, with the collector/cathode (C) electrodes and emitter/anode (E)/(A) electrodes of chips 106a, c being provided on the surfaces facing the opposite direction compared to their counterparts on chips 106b, d.

Package 100 is configured in a half-bridge structure, with ‘up’ chips 106b, d connected between a DC positive power terminal 110b (‘DC+’) and an output power terminal 102 (‘AC’), and ‘lower’ chips 106a, c connected between the output power terminal 102 (‘AC’) and a DC negative power terminal 110a (‘DC−’). These positive and negative power terminals, along with their corresponding ‘up’ and ‘lower’ chips, therefore form high-and low-sides of the half-bridge structure of package 100.

In package 100, chips 106c and 106d are diode-based devices, such as a fast response diode (FRD) or a schottky diode (SBD), or any other suitable diode. Chips 106a, c, meanwhile, are transistor-based devices, such as an IGBT or a MOSFET. However, it will be understood that the configuration of semiconductor chips within the package, including the choice of semiconductor chip and their positioning within the packaging, may be selected based on the desired or intended functionality of the semiconductor package. Beneficially, a symmetric die layout (e.g. with the positioning of the respective diode and transistor chips on the high and low sides of the half-bridge structure being mirrored) such as that depicted in FIG. 2 may facilitate the balancing of any parasitics on the low and high sides of the semiconductor packaging. it will be understood that for an IGBT such as chips 106a, b a voltage difference between the gate terminal and its electrodes determines the on/off status of a power current path between the emitter electrode and the collector electrode.

The chips 106a-d are directly attached to the power terminals by interface layers 104a, b and 108a, b. The interface layers may be formed by soldering, sintering, or any other suitable means. For example, the power terminals may be bonded to the chips via direct lead bonding (DLB). As such, the package 100 does not require a baseplate or a substrate, as the functions of these components may be provided by the power terminals. As a result, package 100 has a compact and low volume structure relative to equivalent existing semiconductor packaging designs.

Additionally, by attaching the chips to the power terminals in this manner, a power loop inductance may be reduced due to the reduction in the length of, or in some cases the complete avoidance of, and chip to terminal bonding wires. The power loop inductance may be further reduced via mutual inductance cancellation resulting from the overlapping of the power terminals 110a, b with power terminal 102. Similar boding methods may also be used for joining the gate/control terminals 114a, b to the chips, with corresponding benefits such as a reduction in gate/control loop inductances and/or common source inductance, for faster communication and switching capabilities.

To further enhance the mechanical stability of the structure, as well as to provide further environmental protection (e.g. against conditions such as high humidity), the package 100 is encapsulated by an encapsulant material 112. The encapsulant material may be, for example, a high temperature epoxy moulding compound, or any other suitable material. The encapsulant may not fully encapsulate the power terminals, and may instead leave a surface of the power terminals unencapsulated for improved cooling capabilities. For example, and in package 100 the ‘lower’ surface of power terminal 102 and/or the ‘upper’ surface of power terminals 110a, b may extend beyond the encapsulant, for attaching to e.g. a heatsink for single sided cooling, double sided cooling and/or liquid based-cooling applications, such as indirect liquid cooling. These cooling technologies may therefore be used to enhance the cooling of the chips 106a-d via the power terminals.

It will be understood that the power capabilities of package 100 may be enhanced by, for example, providing additional packages in parallel to package 100, or otherwise increasing the number of semiconductor chips provided within the module itself.

For example, FIG. 3 illustrates a schematic cross-sectional view of a flip chip semiconductor package 200 according to an embodiment of the disclosure. The structure and functionality of package 200 is similar to that of package 100 in FIG. 2. However, in contrast to the four die structure of package 100, package 200 comprises eight such dies, including four ‘lower’ chips or switches and four (flipped) ‘up’ chips or switches. The example chips depicted in package 200 form a symmetric structure, with the diode based chips (FRD) forming inner columns of chips 202a, b within the package and the transistor based chips (IGBT) forming outer columns of chips 204a, b within the package.

In addition to the benefits described with respect to package 100, the structure of package 100 provide easy scalability without any requirements to redesign the semiconductor package, by replicating rows 206a, b of semiconductor chips to provide additional such rows. For example, package 200 may comprise further third, fourth, etc. chip rows comprising the same chip layout as first and second chip rows 206a, b. In general therefore, a semiconductor package such as packages 100 and 200 may comprise N rows of chips each comprising M columns of chips, in a design and layout that may be selected based on the requirements or desired functionality for an intended use.

The number of chips provided in a semiconductor package according to the present disclosure may be further increased by providing a stacked chip structure, to facilitate higher power density packaging. One such example structure provided in FIG. 3, which illustrates a schematic cross-sectional view of a flip chip semiconductor package 300 according to an embodiment of the disclosure.

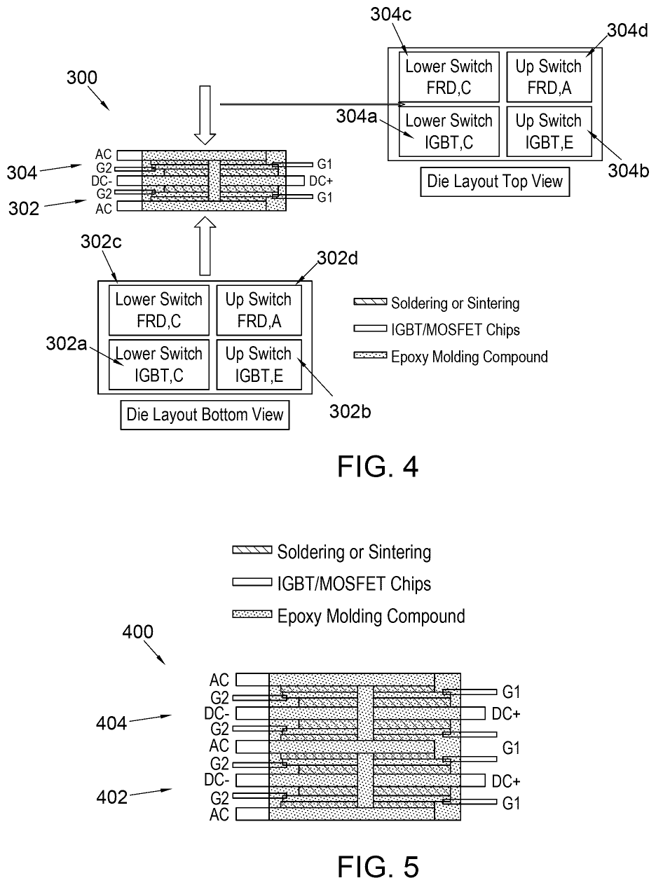

Semiconductor package 300 comprises a first layer of semiconductor chips 302 and a second layer of semiconductor chips 304, separated by the positive and negative DC power terminals. As depicted in FIG. 4, the structure of layer 302 is identical to that shown in package 100, while the structure of layer 304 mirrors that of layer 302 along the DC+/− power line axis. As a result, the ‘lower’ and ‘up’ chips or switches in layer 304 are flipped relative to the corresponding chips of the first layer 302. A second AC power line is provided for the upper layer 304.

It will be understood that other chip structures, for example that shown in package 200, may also be stacked in an equivalent manner to package 300. The stacked structure of package 300 enhances the power density of the package relative to e.g. a single layer with a corresponding chip layout as shown in FIG. 2.

As shown in FIG. 5, the stacked structure of package 300 may be extended to any number of layers. For example, package 400 comprises a first structure 402 between the first (bottom) AC power terminal and second AC terminal, and a second structure 404 between the second AC power terminal and the third (top) AC power terminal. Both structures 402 and 404 correspond to the configuration of package 300 of in FIG. 4. It will therefore be understood that the package 400 may be generalised to any number N of such layer structures, with additional layer structures provided above the third AC power terminal and interleaved with further AC power terminals, such that a power terminal separates each layer structure in the stacked semiconductor package.

In all such cases, the configuration of semiconductor dies in each layer structure of the stacked structure may be identical, or some or all of the layer structures may comprise different semiconductor die configurations. A layer of the stacked structure may be e.g. the portion of the stacked structure between each interleaving power terminal.

The multiple layers of power terminals provided in stacked packages such as those of package 300 and 400 facilitate further reductions in power loop inductances, for improved efficiency, particularly in high frequency operations. This reduction is further enhanced as some or all of the power terminals in the structure may (at least partially) overlap with one another, resulting in mutual power loop inductance cancellation.

The high power density and compact profile provided by such a stacked semiconductor package makes it particularly suitable for some applications, such as wide bandgap (WBG) semiconductor packaging.

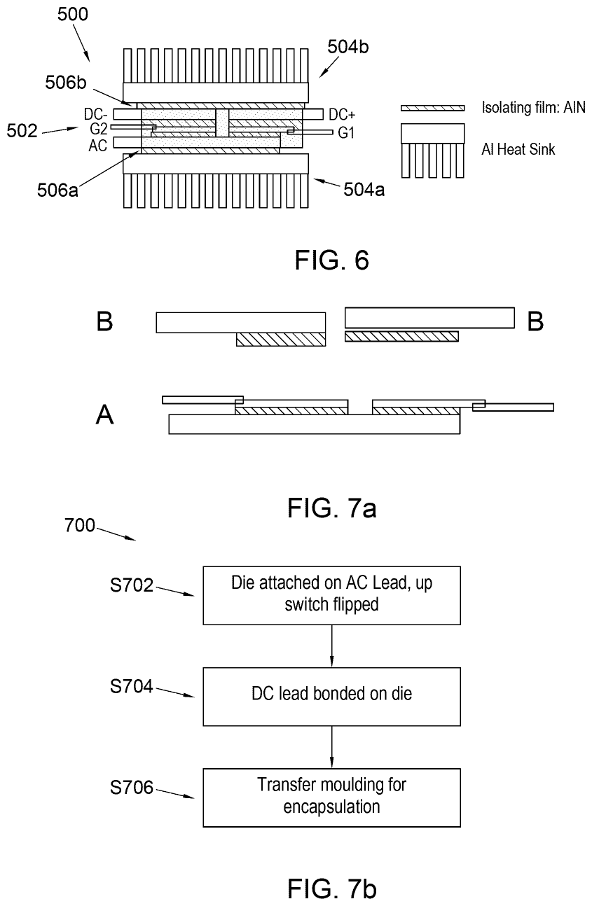

FIG. 6 illustrates a schematic cross-sectional view of a double side cooling (DSC) flip chip semiconductor package 500, according to an embodiment of the disclosure. As briefly discussed above, the bottom and top power terminals of the semiconductor package may extend beyond the encapsulating material. As such, one or both of the power terminals may be attached to a heatsink 504a, b via an electrically insulating thermal interface layer 506a, b. It will be understood that while package 500 is depicted with pin-fin DSC technology, the modules of the present disclosure are compatible with any other cooling configurations, including but not limited to single sided cooling (SSC) or indirect liquid cooling. Similarly, while the semiconductor module 502 corresponds to package 100 of FIG. 2, it will be understood that any semiconductor module or package of the present disclosure, such as packages 200, 300 and 400, may be provided with such cooling capabilities.

The heatsinks 504a, b may be attached to the module 502 via any suitable means, such as sintering or soldering.

In all embodiments, the power terminals may comprise any suitable materials, for example copper (Cu), nickel (Ni), or aluminium (Al) or their alloys. The power terminals may be further coated with silver (Ag) or gold (Au) or the like. The dimensions of the power terminals may be determined based on the power requirements of a given semiconductor package for its intended use.

It will be appreciated that packages or modules according to the present disclosure may comprise different types/numbers of power semiconductor dies that are suitably interconnected to form a different circuit structure (e.g., multiple half-bridge structures, an AC-to-DC power converter, a buck or boost DC-to-DC power converter etc.).

FIGS. 7a and b illustrative a manufacturing method 700 for a semiconductor module according to an embodiment of the disclosure. The method 700 comprises attaching S702 one or more semiconductor dies to a first power terminal, to form structure A of FIG. 7a. the dies may be attached to the power terminal by e.g. soldering or sintering, or any other suitable means, for example direct lead bonding (DLB). The dies may include one or more ‘flipped chip’ dies, attached to the power terminal in a ‘flipped’ orientation. In a second step S704, a second and third power terminals (structure B of FIG. 7a) are attached to the dies, again by any suitable attaching means such as soldering or sintering. The second power terminal may be attached to all of the ‘unflipped’ dies, while the third power terminal may be attached to all of the ‘flipped’ dies. Finally, after connecting structures A and B of FIG. 7a, the package may be encapsulated in step S706, for example by transfer moulding. Optionally, the encapsulated package may then be cured, for example via a heat curing technique, to harden the encapsulant material.

The constructed module may then be attached to any suitable cooling technologies or devices, such as heatsinks, as discussed above.

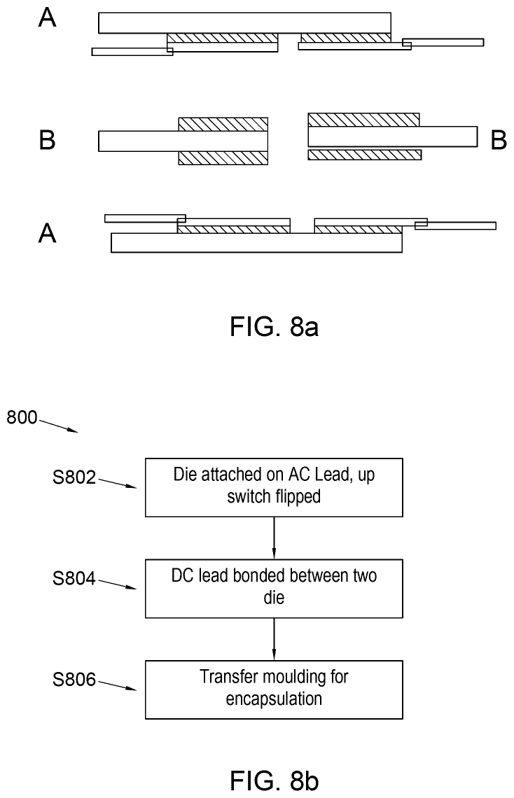

FIGS. 8a and b illustrative another manufacturing method 800 for a semiconductor module according to an embodiment of the disclosure. The steps of method 800 generally correspond to those of method 700. However, in method 800, step S802 additionally comprises attaching a second set of dies to a fourth power terminal, to form the second structure A of FIG. 8a. Both structures A of FIG. 8a may be formed in the same manner as the structure A of FIG. 7a. Then, in step S804, the power terminals of structure B are attached to the dies between the two ‘A’ structures, such that the package comprises two ‘A’ structures sandwiching a ‘B’ structure. The attaching of structure B to each of the two ‘A’ structures in step S804 may otherwise be identical to that in step S704 of method 700. Finally, in step S806, the structure is encapsulated and optionally cured, as in step S706, and the constructed module may then be attached to any suitable cooling technologies or devices, such as heatsinks, as discussed above.

It will be understood that the steps of methods 700 and 800 may be repeated to form stacked semiconductor packages, such as those depicted in FIGS. 4 and 5.

It will be appreciated that the steps of methods 700 and 800 may be performed in a temporal order that is different from the order of description. For example, steps S702/802 and S704/804 may be performed simultaneously, or steps S704/804 may be performed prior to steps S702/802 by attaching the dies to the second and third power terminals prior to the first/fourth power terminals.

The terms “having”, “containing”, “including”, “comprising” and the like are open and the terms indicate the presence of stated structures, elements or features but not preclude the presence of additional elements or features. The articles “a”, “an” and “the” are intended to include the plural as well as the singular, unless the context clearly indicates otherwise.

The skilled person will understand that in the preceding description and appended claims, positional terms such as ‘top’, ‘bottom’, ‘lateral’, ‘vertical’, etc. are made with reference to conceptual illustrations of a semiconductor device, such as those showing standard cross-sectional perspectives and those shown in the appended drawings. These terms are used for ease of reference but are not intended to be of limiting nature. These terms are therefore to be understood as referring to a device when in an orientation as shown in the accompanying drawings.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the disclosure, whether alone or in any appropriate combination with any other feature disclosed or illustrated herein.

1. A semiconductor module, comprising:
a plurality of semiconductor dies, the plurality of semiconductor dies comprising at least one first semiconductor die and at least one second semiconductor die, each of the first and second semiconductor dies comprising a first surface and an opposite second surface;
a first gate terminal operably connected to the first surface of the first semiconductor die;
a second gate terminal operably connected to the first surface of the second semiconductor die
a first power terminal attached to the second surface of the first semiconductor die and the first surface of the second semiconductor die;
a second power terminal attached to the first surface of the first semiconductor die;
a third power terminal attached to the second surface of the second semiconductor die; and
an encapsulant encapsulating the plurality of the semiconductor dies and at least part of the first, second and third power terminals.

2. The semiconductor module of claim 1, wherein the semiconductor module is a power semiconductor module, and wherein the plurality of semiconductor dies is a plurality of power semiconductor dies.

3. The semiconductor module of claim 1, wherein the at least one first semiconductor die and the at least one second semiconductor die are directly attached to the respective first, second and third power terminals.

4. The semiconductor module of claim 3, wherein the at least one first semiconductor die and the at least one second semiconductor die are directly attached to the respective first, second and third power terminals via soldering and/or sintering.

5. The semiconductor module of claim 1, wherein the encapsulant comprises an epoxy moulding compound.

6. The semiconductor module of claim 1, wherein each of the first, second and third power terminals comprising a first surface and an opposite second surface, wherein:
the first surfaces of the first and second power terminals are attached to the first semiconductor die;
the first surfaces of the first and third power terminals are attached to the second semiconductor die; and
the second surfaces of the first, second and third power terminals extends beyond the encapsulant.

7. The semiconductor module of claim 6, further comprising
a heatsink attached to either (i) the second surface of the first power terminal; or (ii) the second surfaces of the second and third power terminals; and
an electrically insulating thermal interface material positioned between the heatsink and the first, second and third power terminals.

8. The semiconductor module of claim 7, wherein the heatsink is a first heatsink the electrically insulating layer is a first electrically insulating layer, wherein
the first heatsink is attached to the second surface of the first power terminal via the first electrically insulating thermal interface material; and
the semiconductor module further comprising:
a second heatsink attached to the second surfaces of the second and third power terminals via one or more second electrically insulating thermal interface materials.

9. The semiconductor module of claim 1, wherein the first and second semiconductor dies form a half-bridge structure.

10. The semiconductor module of claim 1, wherein the at least one first semiconductor die comprises at least two first semiconductor dies, and wherein the at least one second semiconductor die comprises at least two second semiconductor dies.

11. The semiconductor module of claim 10, wherein the at least two first semiconductor dies and the at least two second semiconductor dies each comprise:
a diode; and
a transistor.

12. The semiconductor module of claim 10, wherein the at least two first semiconductor dies comprise at least four first semiconductor dies, and wherein the at least two second semiconductor dies comprise at least four second semiconductor dies.

13. The semiconductor module of claim 12, wherein the at least four first semiconductor dies and the at least four second semiconductor dies each comprise:
two or more diodes; and
two or more transistors.

14. The semiconductor module of claim 11, wherein the diodes and transistors are arranged such that the diodes of the first and second semiconductor dies are positioned between the transistors of the first semiconductor and second semiconductor dies.

15. The semiconductor module of claim 1, wherein the first power terminal comprises regions which overlap with the second and/or third power terminals.

16. The semiconductor module of claim 1, wherein the plurality of semiconductor dies comprises at least one third semiconductor die and at least one fourth semiconductor die, each of the third and fourth semiconductor dies comprising a first surface and an opposite second surface;
a third gate terminal operably connected to the first surface of the third semiconductor die;
a fourth gate terminal operably connected to the first surface of the fourth semiconductor die;
a fourth power terminal attached to the second surface of the third semiconductor die and the first surface of the fourth semiconductor die;
the second power terminal comprising a first surface attached to the first semiconductor die and an opposite second surface, wherein the second surface is attached to the first surface of the third semiconductor die;
the third power terminal comprising a first surface attached to the second semiconductor die and an opposite second surface, wherein the second surface is attached to the second surface of the fourth semiconductor die; and
the encapsulant encapsulates at least part of the fourth power terminal.

17. The semiconductor module of claim 16, wherein the plurality of semiconductor dies, second power terminal and third power terminal form a first module layer between a first surface of the first power terminal and a first surface the fourth power terminal; the semiconductor module further comprising:
one or more second module layers, the one or more second module layers comprising an identical structure to the first module layer; and
one or more further power terminals, attached to the second module layers; wherein
a first one of the second module layers is attached to a second surface of the fourth power terminal.

18. The semiconductor module of claim 17, wherein one or more second module layer comprise a plurality of second module layers forming a stacked structure; and
the one or more further power terminals interleaving the second module layers in the stacked structure, such that the second module layers are separated from one another by respective further power terminals.

19. A method of manufacturing a power semiconductor module, comprising:
attaching a plurality of semiconductor dies to a first power terminal, wherein the plurality of semiconductor dies comprises at least one first semiconductor die and at least one second semiconductor die, each of the first and second semiconductor dies comprising a first surface and an opposite second surface, the first power terminal attached to the second surface of the first semiconductor die and the first surface of the second semiconductor die;
operably connecting a first gate terminal operably to the first surface of the first semiconductor die;
operably connecting a second gate terminal to the first surface of the second semiconductor die;
attaching a second power terminal to the first surface of the first semiconductor die;
attaching a third power terminal to the second surface of the second semiconductor die; and
and encapsulating the plurality of the semiconductor dies and at least part of the first, second and third power terminals.

20. The method of claim 19, wherein at least one of:
(i) the at least one first semiconductor die and the at least one second semiconductor die are directly attached to the respective first, second and third power terminals via soldering and/or sintering;
(ii) the method comprises curing the semiconductor module via a heat curing process; and
(iii) the method comprises:
attaching a second plurality of semiconductor dies to a fourth power terminal, wherein the plurality of semiconductor dies comprises at least one third semiconductor die and at least one fourth semiconductor die, each of the third and fourth semiconductor dies comprising a first surface and an opposite second surface, the fourth power terminal attached to the second surface of the third semiconductor die and the first surface of the fourth semiconductor die;
operably connecting a third gate terminal operably to the first surface of the third semiconductor die;
operably connecting a fourth gate terminal to the first surface of the fourth semiconductor die;
attaching the second power terminal to the first surface of the third semiconductor die, wherein the first and third semiconductor dies are attached to opposite surfaces of the second power terminal;
attaching the third power terminal to the second surface of the fourth semiconductor die, wherein the second and fourth semiconductor dies are attached to opposite surfaces of the third power terminal; and
wherein encapsulating the plurality of the semiconductor dies and at least part of the first, second and third power terminals comprises encapsulating at least part of the fourth power terminal.

21.-22. (canceled)
